(19) United States
(12) Patent Application Publication
(10) Pub. No.: US 2010/0297440 A1
(43) Pub. Date: Nov. 25, 2010

(54) Method for the Application of a High-Strength-Coating to Workpieces and/or Materials

(76) Inventor: Oliver Nöll, Schwalmtal (DE)

Correspondence Address: Ballard Spahr LLP, SUITE 1000, 999 PEACHTREE STREET, ATLANTA, GA, 30309-3915, US

(21) Appl. No.: 12/595,355

(22) PCT Filed: Apr. 11, 2008
(86) PCT No.: PCT/EP08/54394

§ 371 Date: Apr. 1, 2010

(51) Int. Cl. C23C 14/34; C23C 28/00; B32B 7/12; B32B 15/04

(52) U.S. Cl. 428/354; 204/192.15; 205/188; 204/450; 205/183; 428/343; 428/457

(57) ABSTRACT

The invention relates to a method for the application of a coating to workpieces and/or materials, comprising the following steps: applying an adhesive layer; and applying a high-strength top layer by plasma coating.

The present invention relates to a method for applying a coating to workpieces and/or materials according to the preamble of claim 1.

### BACKGROUND

Surface coatings have been used for quite some time to improve the service life and coefficient of friction of workpieces and materials. Coatings containing carbon (“diamond-like carbon”) are used in particular, as well as coatings composed of silicon oxides (SiOₓ) or other materials.

Such coatings are applied to workpieces and/or materials in particular by use of plasma coating methods such as the plasma enhanced chemical vapor deposition (PECVD) process.

This process is a special form of chemical vapor deposition (CVD), in which thin layers are deposited by means of a chemical reaction in a vacuum chamber, and the material which is to be used for the coating is in the gas or vapor phase.

In addition, the PECVD process is assisted by use of plasma. To this end, a strong electrical field is applied between the substrate to be coated and a counterelectrode, by means of which plasma is ignited. The plasma causes the bonds of the reaction gas to break, and the gas decomposes into ions or radicals which deposit on the substrate and at that location bring about the chemical deposition reaction. In this manner a higher deposition rate can be achieved, at a lower deposition temperature, than with CVD.

Coatings containing carbon and/or silicon oxide, in particular coatings composed of DLC, are characterized by great hardness, high resistance to tribological stresses, and a high degree of smoothness, combined with a low coefficient of friction in the range of μ=0.1.

This type of coating is therefore particularly suited for punching, cutting, boring, and screw driving tools, machining tools, prostheses, ball or roller bearings, gear wheels, pinions, drive chains, sound and drive units in magnetic recording devices, and surgical and dental instruments. The coating is particularly suited for knives having exchangeable blades, for example surgical scalpels, and/or blades and/or cutters for industrial applications.

The workpieces and/or materials to be coated may be composed in particular of metals, ceramic, or plastics, may contain such materials, or may represent mixtures or composites of said materials.

In many cases, however, such coatings have very poor adherence to the referenced workpieces and/or materials. There are various reasons, as follows:
1. Since PECVD coatings are applied under vacuum in a suitable vacuum chamber, the workpieces and/or materials to be coated undergo a minimal increase in volume during evacuation of the chamber due to the fact that, although they are actually composed of incompressible solids, the workpieces and/or materials frequently have gas-filled microcavities which enlarge their volume during the evacuation. After the coating is applied, the workpieces and/or materials are once again placed under atmospheric pressure, resulting in shrinkage of same. This shrinkage may result in peeling of the coating when there is inadequate adhesion of the coating to the surface of the workpieces and/or materials.
2. The internal stress of the workpieces and/or materials to be coated is frequently different from that of the coating. This is the result of the type of manufacturing. Thus, hard metal workpieces or materials undergo extreme internal stress, or, depending on the composition, experience very high internal stresses in the flame spraying process.
3. Powder mixtures are also used which do not allow, and even repel, a subsequent DLC coating in the strict sense when such powder mixtures must or should be free of carbon.

Various approaches are known from the prior art which have the objective of improving the adhesion of a DLC layer to a material and/or workpiece.

For example, a method for improving the adhesion of a DLC layer to super-speed steel (SSS) is known in which the steel is nitrided using nitrogen. However, this method has proven to be difficult in practice because of the effect of heat.

### SUMMARY OF THE INVENTION

The object of the present invention, therefore, is to provide a well-adhering coating for workpieces and/or materials which imparts to the surface great hardness, high toughness, high resistance to tribological stresses, a high degree of smoothness, and a low coefficient of friction, and which also is resistant to point loads.

A further object of the present invention is to provide a well-adhering coating for workpieces and/or materials which is resistant to point loads and at the same time has suitable surface properties with regard to surface tension and resistance to dyes and cleaning agents such as acids and bases, has electrically insulating and heat-conducting properties, and/or is biocompatible and has antiallergic properties.

A further object of the present invention is to provide a well-adhering coating for cutting, machining, boring, forging, milling, screw driving, and punching tools which has a long lifetime and/or service life.

A further object of the present invention is to provide a well-adhering coating which extends the lifetime and/or service life and which is suitable for ultra-sharp blades.

These objects are achieved by the features of present claim 1. The subclaims state preferred embodiments. It is noted that the referenced ranges are consistently understood to include the respective limit values.

Thus, according to the invention a method for applying a coating to workpieces and/or materials is provided which comprises the following steps:
b) Application of an adhesive layer; and
c) Application of a high-strength top layer by plasma coating.

The workpiece or the material may in particular be composed of ceramic, iron, steel, high-alloy steel, nickel, cobalt, and alloys thereof with chromium, molybdenum, and aluminum, copper and copper alloys, titanium, or alloys which contain the above-referenced materials. The workpiece or the material may also be composed of metals and/or metallic alloys based on Zn, Sn, Cu, Fe, Ni, Co, Al, Ti, and refractory metals such as Mo, W, Ta, etc. Also suitable are sintered metal materials and metal-ceramic composites (MMC) and metal-polymer composites, as well as ceramic materials composed of oxides, carbides, borides, and nitrides.

The workpiece may also be composed of plastic or a mixture of plastics. Of course, mixtures of alloys or composites of the referenced materials are also suitable.

As stated at the outset, according to the present invention the high-strength top layer is applied by plasma coating. In addition to an inert protective gas, a reaction gas containing carbon or silicon is preferably used, for example methane (CH₄), ethene (C₂H₄), acetylene (C₂H₂), methyltrichlorosilane (CH₃SiCl₃), or tetramethyldisiloxane (C₄H₁₄OSi₂).

In this manner, for example, a top layer containing carbon may be deposited which frequently has diamond-like properties and structures, and which therefore is also referred to as a diamond-like carbon (DLC) layer. Such layers are used as particularly preferred embodiments of the invention.

In contrast, a silicon nitride layer as the top layer is produced using the reaction gases ammonia and dichlorosilane. For silicon dioxide layers the reaction gases silane and oxygen are used. Such layers are likewise particularly preferred embodiments of the invention.

For producing metal/silicon hybrids (silicides) as the top layer, tungsten hexafluoride (WF₆), for example, is used as reaction gas.

Titanium nitride layers as the top layer for the hardening of tools are produced from tetrakis(dimethylamido)titanium (TDMAT) and nitrogen. Silicon carbide layers are deposited from a mixture of hydrogen and methyltrichlorosilane (CH₃SiCl₃).

In principle, for deposition from the gas phase the material to be deposited must be made available for the method (“reaction gas”). Suitable materials are those which exist in gaseous form at room temperature, or liquid, highly volatile materials. A device is known for the first time from DE 10 2007 020 852 by the applicant for the present invention, by means of which materials which exist in solid form at room temperature (such as TiO₂, for example) may be made available for deposition from the gas phase in order to functionally dope carbon oxides and/or silicon oxides, or to produce pure coatings based on said solids. The disclosure of DE 10 2007 020 852 is incorporated in full into the present application.

The deposition of layers containing titanium is particularly preferred, preferably using titanium isopropoxide (C₁₂H₂₈O₄Ti) as starting material.

The adhesive layer according to the invention contributes in various ways to improved adhesion of the top layer to the workpiece or material, as follows:
It compensates for unevenness in the material surface
It ideally has an intermediate internal stress, i.e., an internal stress between that of the material and that of the top layer material
The intermediate layer is applied so that its internal stress is different from that of the material, i.e., the substrate, resulting in a compensating effect.

The workpiece to be coated or the material to be coated is often made of metal, in particular steel or stainless steel, aluminum, or titanium, and the alloys thereof. The surface of these metals is relatively soft and easily plastically deformable compared to the applied top layer containing carbon or silicon. In contrast, the referenced top layer is extremely hard but brittle. As a result, in many situations, for example under extremely high point loads, the workpiece or the material is plastically deformed, and due to its brittleness the top layer cannot conform to this deformation and therefore fractures or ruptures. For purposes of illustration, this behavior may be compared to a thin sheet of plate glass, resting on a mattress, which breaks under a point load.

Thus, tools and materials coated with such a top layer have short lifetimes and/or service lives in certain fields of application and load scenarios.

For this reason, in one preferred embodiment of the method according to the invention, before step b) the method includes the following step:
a.1) Application of a supporting layer to the workpiece and/or the material.

These supporting layers do not have the extreme hardness of the top layer, but do have adequate tough-hard characteristics to prevent yielding under high point loads, thus avoiding fracture or chipping of the top layer. The characteristics of this supporting layer are described in greater detail below.

In a further preferred embodiment of the method according to the invention, before step b) the method includes the following step:
a.2) Pretreatment or activation of the workpiece and/or the material by sputtering.

In this case it may also be provided that the workpiece and/or the material itself as well as the optional supporting layer subsequently applied are pretreated or activated by sputtering. Step a.2) may be carried out before and/or after step a.1).

The term “sputtering” or “sputter etching” refers to a physical process in which atoms are released from a solid by bombardment with high-energy ions and pass into the gas phase. Similarly as for PECVD, these ions are often produced by generation of a plasma, using a high-frequency electromagnetic alternating field in a vacuum chamber. Noble gases such as argon (Ar₂), for example, are generally suitable as reaction gas. For a high-strength base substrate (for example, a flame spray layer based on tungsten carbide) oxygen (O₂) is preferably used, and for nonferrous materials such as brass, bronze, aluminum, etc. a mixture of oxygen (O₂) and hydrogen (H₂) is preferably used.

Depending on the substrate, a mixture of H₂ and O₂ is also used when the subsequent intermediate layer or the substrate to be coated requires such. The substrate surface is cleaned down to the nanorange by ion etching, and in a nominal sense is ablated. This ablation of the surface, for example using O₂, is measurable after a short period of time and varies in a range of 100 nm per hour. This ensures that the substrate surface to be treated is free of all impurities. When bronze and brass in particular are used as the substrate to be coated, use of a mixture of H₂ and O₂ for cleaning the surface, and in the broadest sense even the activation, is necessary to achieve any adhesion at all.

The supporting layer is preferably applied using at least one method selected from the following group:
High-velocity flame spraying,
Plasma spraying,
Flame spraying,
Anodizing, including hard anodizing,
Electroplating,
Powder coating and/or
Electrophoresis,
Hard anodizing.

For high-velocity flame spraying (HVOF), the spray powder is sprayed at a very high velocity onto the substrate to be coated. The heat for melting the powder is produced by the reaction of oxygen and fuel gas, for example vaporized kerosene, in the combustion chamber.

Temperatures up to approximately 3000° C. are achieved in the flame. The gas is expanded by the reaction and accelerates the spray powder to a high velocity.

For plasma spraying, a plasma burner is generally used in which an anode and cathode are separated by a narrow gap. An arc is generated between the anode and cathode by direct current voltage. The gas flowing through the plasma burner is conducted by the arc and is ionized. The ionization or subsequent disassociation produces a superheated (up to 20,000 K) electrically conductive gas composed of positive ions and electrons. Powder which is melted by the high plasma temperature is injected into this generated plasma jet. The plasma gas stream entrains the powder particles and deposits them at a velocity of up to 1000 m/s on the workpiece to be coated. After a brief period the gas molecules return to a stable state and cease to release energy, thereby dropping the plasma temperature after traveling a short distance. The plasma coating is generally carried out under atmospheric pressure. The kinetic and thermal energy of the plasma is of particular importance for layer quality. Argon, helium, hydrogen, oxygen, or nitrogen are used as gases.

Flame spraying with powder is the oldest process using the thermal spraying technique. As a result of using the fuel gas/oxygen flame as the heat source, only low-melting metals and alloys can be processed. Dense, thick layers of up to 2.5 mm may be achieved by flame spraying with subsequent smelting of hard alloys based on nickel or cobalt, for example. Addition of carbides greatly increases the hardness.

In all three cases the coating material is present in the form of a powder. Metal-bonded carbides such as tungsten carbide, chromium carbide, titanium carbide, or silicon carbide, or oxides such as aluminum oxide, titanium dioxide, chromium oxide, magnesium oxide, and zirconium oxide and the alloys and mixtures thereof are preferred.

For flame spraying using wire, the coating material is present in the form of wire. The layer material is applied as a result of the fuel gas/oxygen flame and the gas velocity. Typical coating materials for this method are metals, for example molybdenum, Cr steel, Cr—Ni steel, Zn, etc.

Anodizing (“eloxal process”) is a process in which an oxidic protective layer is applied to an aluminum workpiece or material by anodic oxidation. In contrast to electroplating methods, the protective layer is not deposited onto the workpiece, but instead an oxide or hydroxide is formed by conversion of the topmost metal zone. A layer 5 to 25 micrometers thick is produced which protects the aluminum from corrosion. In contrast, the natural oxide layer of the aluminum is only a few nanometers thick. The hardness of the anodized layer is approximately 8-9 on the Mohs hardness scale, i.e., between quartz and corundum.

Hard anodizing (hardcoating) refers to the oxidation of aluminum surfaces which are produced in supercooled electrolytes. This coating is characterized by high wear, heat, corrosion, and electrical resistance. The coating also has good sliding properties with greatly reduced inertial forces. Since the hard anodized layer is formed from the base material itself, there are no adhesion problems. The good wear characteristics result from the aluminum oxide which is formed during the process and which constitutes the hard anodized layer. A related method is hard anodizing for extruded profiles and rotary parts, and for diecasting, sand casting, and permanent mold casting, and forged and wrought alloys. This term includes several anodizing techniques by means of which thick (50-100 μm), dense oxide layers may be produced at low temperature. Such layers are more abrasion-resistant than the best tempering steels, and have electrical insulation properties comparable to porcelain. Hard-anodized products are used in electrical and mechanical applications. Various impregnating substances such as lanolin, Teflon, molybdenum sulfide, etc. are suitable for reducing the coefficient of friction. With regard to the very high layer thicknesses, in certain cases altered dimensions of the workpiece may be expected after anodizing.

Electroplating refers to the electrochemical deposition of metallic precipitates onto workpieces or materials. In the process, current is passed through an electrolytic bath. The metal to be applied (for example, copper, nickel, cobalt, manganese, chromium, or certain alloys) is located at the anode (consumable electrode), and the workpiece or material to be coated is located at the cathode. The electrical current releases metal ions from the consumable electrode and deposits them on the item by reduction. The item to be processed is coated uniformly on all sides with copper or another metal. The longer the item remains in the bath and the higher the electrical current, the thicker the metal layer (copper layer, for example). The surface hardness of the workpiece or material may be increased in this manner.

Powder coating is a coating process in which a material or workpiece which is generally electrically conductive is coated with coating powder. The powder is electrostatically or tribostatically sprayed onto the substrate to be coated and then burned in. The workpiece must be thoroughly degreased and optionally treated with corrosion protection beforehand. In current operations the burn-in temperatures may vary greatly, depending on the application. Typical burn-in conditions are between 140 and 200° C. Various binders are currently used, although coating powders based on polyurethane, epoxy, or polyester resins are typically employed. The burn-in results in permanent adhesion (purely mechanical bonding), and a uniform, dense coating is achieved which results in part from coagulation (quasi-sintering) and in part from fusing of the particles. The powder may also be applied by fluidized bed sintering. In this method a heated workpiece is briefly immersed in a plastic powder which is fluidized using compressed air. The powder fuses to the surface to produce a plastic layer as a result of the workpiece melting the powder under heat.

A number of the referenced methods may also particularly preferably be combined. For example, a combination of electrophoretic and electroplating deposition may be [carried out] in consecutive steps. For example, a ceramic layer (yttrium-stabilized zirconium oxide, for example) may first be electrophoretically produced on a workpiece and then sintered at 1100° C. to produce an open porous layer. In the next step nickel, for example, is deposited into the pores of the layer by electroplating. The bonding of the composite supporting layer produced in this manner to the workpiece or the material is improved by a final thermal treatment.

The basic principle of electrophoresis is the migration of dispersed particles in an electrical constant field and deposition thereof onto an electrode. Ceramic powders (such as yttrium oxide (Y₂O₃) and titanium oxide, for example) are generally dispersed in ethanol, for example, or a water-ethanol mixture. A dispersion agent, for example 4-hydroxybenzoic acid, is frequently used which at the same time is able to act as binder in the green layer (unsintered, previously deposited layer).

The coating is generally applied at a direct current voltage of 5-200 V. The workpiece or material to be coated is used as coating substrate, which at the same functions as an electrode. The counterelectrode is made of graphite, for example.

The electrophoretic coating is generally followed by air drying of the layer for several hours. Sintering is then performed at a temperature between 800 and 1500° C. Supporting layers produced in this manner may have a very high porosity of up to 50% after sintering.

In addition, the supporting layer is preferably at least one layer selected from the following group:
Anodized layer,
Ceramic layer,
Chromium(VI) layer, and/or
Corundum layer.

An anodized layer is a layer that is applied using the above-mentioned anodizing method. Ceramic layers may be applied using various of the referenced methods, in particular the referenced spraying methods and the electrophoretic methods. A chromium(VI) layer is generally applied by electroplating. Corundum layers are composed of Al₂O₃, and with a Mohs hardness of 9 represent the second-hardest mineral after diamond. Corundum is an industrial ceramic, and is likewise applied as a coating on a workpiece or material using the referenced spraying methods and the electrophoretic methods, for example.

The adhesive layer is particularly preferably applied to the workpiece and/or the material by plasma coating.

Said adhesive layer preferably contains elements from subgroups 6 and/or 7 [of the periodic table]. Compounds containing the elements Cr, Mo, W, Mn, Mg, Ti and/or Si, in particular mixtures thereof, are preferred. Likewise, the individual components may be distributed in a graduated manner over the depth of the adhesive layer. Si is particularly preferred. TMS, for example, which is highly volatile under vacuum conditions, is suitable as reaction gas.

In one particularly preferred embodiment a plurality of gases is used in step a.2). In this embodiment step a.2) thus represents a multi-gas sputtering method, the advantages of which are described in greater detail below.

It is particularly preferred to carry out step b) and/or step c) under an inert and/or reducing atmosphere.

Providing an inert and/or reducing atmosphere has various objectives, as follows:
The surface of a metallic workpiece and/or material is prevented from oxidizing and therefore passivating, which may impair the subsequent adhesion of the bonding layer and/or the top layer;
The production of CO and/or CO₂ during the deposition of carbon is prevented, which would otherwise result in the formation of shrink holes, gas bubbles, and microcavities in the carbon-containing layer and thus produce a rough, less dense surface with less load-bearing capacity and also greatly impair the adhesion of the top layer.

An inert and/or reducing atmosphere may be provided in various ways. On the one hand, the deposition in steps b) and/or c) may be carried out under a protective gas atmosphere, for example by simultaneously feeding Ar₂.

On the other hand, before initiating steps b) and/or c) the chamber may be flushed with a protective gas such as Ar₂, for example, to expel any residues of an oxidizing gas such as O₂ from the chamber and/or as a transition for introducing a flushing cycle using nitrogen.

In a likewise particularly preferred embodiment of the method according to the invention, the gas feed of at least two different gases is supplied in the form of opposing ramps
in step a.2), and/or
in the transition from step b) to step c).

In the context of the present invention, the term “in the form of opposing ramps” means that during the sputtering or the PECVD process the minute volume of at least one reaction gas is decreased in a stepped or stepless manner, whereas the minute volume of another gas is increased in a stepped or stepless manner.

The ramps are described herein for the first time. According to the invention, these ramps have different functions on the one hand in step a.2) (sputtering), and on the other hand in the transition from step b) to step c) (PECVD).

For sputtering, the ramps have the effect that a reaction gas is successively displaced by another reaction gas, which may be meaningful for subsequent process steps in which, for example, the reaction gas that is first used causes interference.

For PECVD, the ramps have the effect that the deposition phases of two materials merge together. This produces a transition region having gradually changing proportions of the various coating materials. This results in a closer mutual interaction of the two layers, and thus, for example, improved adhesion of the top layer to the adhesive layer.

The key aspect of said ramps is that a gradual transition from at least one reaction gas to at least one other reaction gas, from coating gas for the intermediate layer to the coating gas for the top layer, must be smoothly set in a temporally coordinated manner, using a specific temporal gradient. The same applies to the changing of the bias number and to further coating parameters, if applicable. It must be ensured that before each transition of the reaction gases the chamber is ramped up or ramped down to the desired bias value to reduce formation of internal stress. The bias value must be set in discrete steps at least 5 seconds but no longer than 15 seconds before starting the setting of the gradient.

It has also proven advantageous to operate with “continuous gradients” during the overall coating process for the top layer in order to obtain stress-free top layers. In practice, this means that during the overall coating process for the top layer the minute volume of the gas feed does not remain constant but instead periodically varies, while the bias voltage is held constant. In this manner, for example, a DLC top layer having a thickness of up to 10μ may be applied so as to be stress-free.

The transition from step b) to step c) may be designed, for example, so that first an adhesive layer containing silicone is applied by plasma coating. To this end, tetramethyldisiloxane (C₄H₁₄OSi₂), for example, is used, which is liquid at room temperature but highly volatile under hypobaric conditions. After a certain period of time the gas minute volume for TMS is successively decreased, and the gas minute volume for the carbon-containing gas acetylene (ethene) is successively increased.

The referenced ramp may be designed as follows: After an optional sputtering step (a.2), 5 s before starting application of the intermediate layer the bias voltage V_{bias} is increased to the level necessary for the coating. The vaporized silane-containing gas TMS is then admitted, with an extremely short ramp (10 s). After the deposition time for the adhesive layer has elapsed, over a period of 500 s the acetylene valve is gradually opened to the desired inlet value. At the same time, the TMS valve is gradually closed over the same time period. The top layer is then applied for the desired period of time. Table 1 illustrates this method with example values:

TABLE 1

| | | | TMS | C₂H₂ |
|---|---|---|---|---|
| Time (s) | Step | V_{bias} | (sccm) | (sccm) |
| 0 | Adhesive layer (b) | 350 | 300 | 0 |
| 600 | Ramp | 350 | 300 | 0 |
| 1100 | Top layer (c) | 350 | 0 | 250 |
| 2000 to X | Top layer (c) | 350 | 0 | 250 |

In principle, the top layer may be applied over any desired period of time. The thickness of the top layer increases proportionally with the duration of the coating. For this reason the variable “X” has been selected as the time value in the above table.

In a departure from the values shown in Table 1, essentially the following parameter ranges are preferred for the various steps:

TABLE 2

| | | TMS | C₂H₂ | Pressure/ |
|---|---|---|---|---|
| Step | V_{bias} | (sccm) | (sccm) | temperature |
| Adhesive layer (b) | 200-500 | 100-500 | 0 | 0.1-2 P [sic; Pa] |
| | | | | 50-150° C. |
| Top layer (c) | 250-600 | 20-150 | 100-500 | 0.01-0.9 P [sic; Pa] |
| | | | | 50-150° C. |

It may also be provided that ramps are operated for the materials used for the adhesive layer. Thus, during the application one material may be successively replaced by another.

In addition, the following process parameters are preferably maintained in the plasma coating chamber during application of the top layer:

TABLE 3

| | |
|---|---|
| Temperature: | 50-150° C., preferably 80° C. |
| Chamber volume: | 200-10,000 L, preferably 900 L |
| Chamber pressure: | 0.0-3.0 Pa, |
| | preferably 0.0-2.0 Pa |
| Bias voltage: | 200-600 volts |
| Duration: | 1-100 min |
| Gas flow: | 50-700 sccm |

The gas concentration in the chamber results from the gas flow, the chamber volume, and the pressure in the chamber. For a chamber having a volume of 900 L and a pressure of 0.0-2.0 Pa, for acetylene (C₂H₂), for example, at a gas flow of 100 sccm (0.1175 g per minute) the resulting concentration is 0.011% of the chamber volume.

Examples of further preferred gas flow settings are 200 sccm (0.2350 g per minute C₂H₂=0.022%), 300 sccm (0.3525 g per minute C₂H₂ (0.033%), 400 sccm (0.4700 g per minute C₂H₂=0.044%), and 500 sccm (0.5875 g per minute C₂H₂=0.055%).

A DLC layer produced in this manner using acetylene as reaction gas has a hardness of 6000-8000 HV and a thickness of 0.90 μm to 5.0 μm.

In principle, O₂ represents an ideal reaction gas for the sputtering, since the ionized oxygen atoms have a high kinetic energy due to their high molecular weight and are therefore able to effectively clean a surface. In addition, oxygen is very inexpensive.

As a rule, however, O₂ is not used in the prior art as pretreatment or activation for sputtering of a metallic material or workpiece, since it has an oxidizing effect on the metallic surface, forming a more or less thick metal oxide layer thereon and thereby passivating the surface. Therefore, for the preparatory sputtering of a metallic material or workpiece one skilled in the art preferably uses nonreactive noble gases such as argon, for example, although these are much more expensive than oxygen. A gas having a reducing effect, such as H₂, would be ideal since it likewise prevents or may even reverse passivation of the metal surface. However, H₂ is not suitable for the sputtering due to its low molecular weight and associated low kinetic energy.

In any event O₂ is suitable for sputtering of plastic surfaces, since there is no concern about passivation of the surface by oxidation.

A further reason for one skilled in the art not to use O₂ in sputtering is the case for which, following the sputtering, a carbon-containing layer is to be applied to the workpiece and/or material by plasma coating. Any residues of O₂ would oxidize carbon to CO and/or CO₂, resulting in formation of shrink holes, gas bubbles, and microcavities in the carbon-containing layer and thus producing a rough, less dense surface with less load-bearing capacity and also greatly impairing the adhesion of the top layer.

However, on account of its very high molecular weight Ar₂ also has disadvantages, since during sputtering it results in a very rough surface on which a top layer that is applied, such as a DLC layer, for example, is of poor quality.

Despite the described reservations concerning O₂ as reaction gas, in one preferred embodiment of the method according to the invention the applicant for the present invention has made use of the advantages of O₂. In one preferred embodiment of the invention the referenced disadvantages are avoided by . . . [ ]¹ ¹ Translator's note: Apparent omission in source.

The reaction gas in step a.2) particularly preferably contains, at least temporarily, the gases H₂ and O₂. As a result of the H₂ present in the reaction gas, the oxidizing effect of the O₂ is decreased and passivation of the metal surfaces does not occur. Under these conditions the molecular weight of O₂ is ideal to produce an effective cleaning effect during sputtering, but without roughening the surface of the workpiece and/or material.

The described method may be carried out as follows: A workpiece is sputtered using H₂ and O₂ in a stoichiometric ratio from 1:2 to 1:8. As described above, the presence of H₂ prevents passivation of the workpiece surface. At time T=400 s the minute volume of H₂ is successively decreased by means of a ramp, and instead Ar₂ is fed into the chamber. At time T=600 s the minute volume of O₂ is successively decreased while the minute volume of Ar₂ remains constant. In this manner the oxygen remaining in the chamber is washed out/expelled without a residue.

To reduce the above-described disadvantageous consequences of sputtering with Ar₂ during this substep, the electromagnetic alternating field may be decreased during this period. Alternatively, an attempt may be made to minimize the duration of this washing step.

The Ar₂ feed is then abruptly terminated, TMS is admitted into the chamber, and the plasma is reignited if necessary. In this phase a silicon adhesive layer is applied to the surface which has been activated by the sputtering. At time T=1600 s the minute volume of TMS is successively decreased by means of an additional ramp, and instead C₂H₂ is fed into the chamber, resulting in deposition of DLC. Thus, during the transition period silicon and carbon are simultaneously deposited, with the silicon portion being successively decreased and the carbon portion being successively increased. In this manner a transition region is created between the adhesive layer and the high-strength top layer which greatly improves the adhesion of the latter to the former. The top layer is then applied over the desired time period. Table 4 illustrates this method with example values:

TABLE 4

| | | | H₂/O₂ | Ar₂ | TMS | C₂H₂ |
|---|---|---|---|---|---|---|
| Time (s) | Step | V_{bias} | (sccm) | (sccm) | (sccm) | (sccm) |
| 0 | Sputter (a.2) | 300 | 50/150 | 0 | 0 | 0 |
| 400 | Ramp 1 | 300 | 50/150 | 0 | 0 | 0 |
| 600 | Sputter (a.2) | 300 | 0/150 | 200 | 0 | 0 |
| 1000 | Ramp 2 | 300 | 0/0 | 200 | 0 | 0 |
| 1200 | Pause | 300 | 0/0 | 0 | 0 | 0 |
| 1205 | Adhesive | 350 | 0 | 50 | 300 | 0 |
| | layer (b) | | | | | |
| 1600 | Ramp | 350 | 0 | 0 | 300 | 0 |
| 2200 | Top layer (c) | 350 | 0 | 0 | 0 | 250 |
| X | Top layer (c) | 350 | 0 | 0 | 0 | 250 |

In principle, the top layer may be applied over any desired period of time. The thickness of the top layer increases proportionally with the duration of the coating. For this reason the variable “X” has been selected as the time value in the above table.

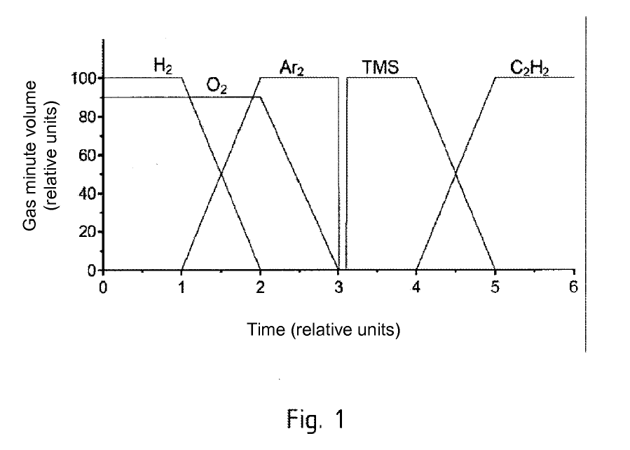

The ramps illustrated by way of example are shown in a diagram in FIG. 1. In a departure from the values shown in Table 1, essentially the following parameter ranges are preferred for the various steps:

TABLE 5

| | | H₂/O₂ | Ar₂ | TMS | C₂H₂ | Pressure/ |
|---|---|---|---|---|---|---|
| Step | V_{bias} | (sccm) | (sccm) | (sccm) | (sccm) | temperature |
| Sputter (a) | 300-600 | 0-200/ | 0-200 | 0 | 0 | 0.5-2 P [sic; Pa] |
| | | 0-200 | | | | 50-50° C. |
| Adhesive layer (b) | 200-500 | 0 | | 100-500 | 0 | 0.1-2 P [sic; Pa] |
| | | | | | | 50-150° C. |
| Top layer (c) | 250-600 | 0 | | 0-90 | 100-500 | 0.01-0.9 P [sic; Pa] |
| | | | | | | 50-150° C. |

The following process parameters are preferably maintained during the overall process:

TABLE 6

| | |
|---|---|
| Temperature: | 50-150° C., preferably 80° C. |
| Chamber volume: | 200-10,000 L, preferably 900 L |
| Chamber pressure: | 0.0-3.0 Pa, |
| | preferably 0.0-2.0 Pa |
| Bias voltage: | 200-600 volts |
| Duration: | 1-100 min |
| Gas flow: | 50-700 sccm |

In a further preferred embodiment of the invention, the referenced disadvantages of the use of O₂ are avoided by displacing H₂ and/or O₂ with Ar₂ in step a.2), using the above-referenced opposing ramps.

The displacement by means of the opposing ramps results in a particularly thorough washout of O₂. In this manner O₂ is completely removed from the coating chamber before the subsequent follow-up treatment, which otherwise could result in the referenced adverse effects in the presence of residual O₂.

Before or after the sputtering step (a.2), or even instead of sputtering step (a.2), a step (a.1) may be inserted for application of a supporting layer. This step may include, for example, use of a method selected from the group comprising
High-velocity flame spraying,
Plasma spraying,
Flame spraying,
Anodizing, including hard anodizing,
Electroplating,
Powder coating, and/or
Electrophoresis.

In a further embodiment of the method according to the invention, the method is carried out in a plasma coating chamber having a flat high-frequency electrode for generating an electromagnetic alternating field, and a frequency generator located outside the chamber, characterized in that the high-frequency electrode has at least two feed lines via which the electrode is supplied with alternating current voltage generated by the frequency generator.

Such a plasma coating chamber is described for the first time in PCT/EP2007/057117 by the applicant for the present invention.

It is thus possible to generate in the chamber an alternating field having very high field intensities. An alternating field generated in this manner has a sufficiently high discharge depth and a high degree of homogeneity. In this way a homogeneous plasma and thus a homogeneous deposition rate is achieved in all regions of the chamber, as manifested by a constant layer thickness and resulting low internal stress differences within the coating thus produced. Both factors further improve the adhesion of the high-strength top layer to be applied according to the invention.

Three or more feed lines are preferably provided, thus allowing establishment of an even more homogeneous alternating field.

The individual feed lines to the high-frequency electrode are preferably regulated separately in such a way that a homogeneous alternating field with uniformly high field intensities may be generated in the overall chamber. This feature greatly improves the quality of the coating.

This may be achieved by use of a so-called matchbox connected between a high-frequency generator and the high-frequency electrode. The matchbox has trim potentiometers, for example, for the individual feed lines to the high-frequency electrode which are regulated separately. The bias voltage setting is the same at all regulators, resulting in identical field intensities and thus a homogeneous alternating field.

Also provided according to the invention is the use of a plasma coating chamber having a flat high-frequency electrode for generating an electromagnetic alternating field, a frequency generator located outside the chamber, and at least two feed lines which supply the high-frequency electrode with alternating current voltage generated by the frequency generator for applying a coating to workpieces and/or materials according to one of the preceding method claims.

The present invention further relates to a coating on workpieces and/or materials, comprising the following layers:
a) An adhesive layer and
b) A high-strength top layer,
   wherein the adhesive layer and top layer have a graduated transition region, i.e., a coating on workpieces and/or materials which may be produced using a method according to the invention.

The material properties of this coating, the starting materials for same, and the process characteristics and parameters for production of same are disclosed in conjunction with the previously discussed method claims, and are disclosed also with regard to the coating as such. This applies in particular to the transition between the adhesive layer and the high-strength top layer, which may be achieved using the referenced ramps.

It is further preferably provided by the invention that said coating also has a supporting layer situated between the workpiece and/or material and the adhesive layer. The characteristics and advantages of this supporting layer are fully disclosed above.

The present invention further relates to an instrument, workpiece or material, or component which is provided with a coating using the above-referenced methods, i.e., a coating as mentioned above.

This instrument may be a surgical instrument, for example, such as a scalpel. The instrument may also be a punching tool. Furthermore, the instrument may be a butcher or meat processing cutting tool.

The service lives of the referenced instruments are sometimes greatly extended by use of the coating according to the invention. Cutting tools coated according to the invention thus retain their sharpness longer, even when used under adverse conditions. This is especially true for butcher or meat processing cutting tools, which must be able to cut soft material (fat, muscle, skin, connective tissue) as well as hard material such as bones and frozen product, for example.

Another example is surgical instruments which must be frequently sterilized, which for instruments not coated according to the invention results in severe corrosion after a short time due to the sterilization conditions (heat, moisture, and pressure). On the one hand the suitability of the instrument as such is adversely affected, and on the other hand in particular the sharpness of the blades that are used is severely impaired.

Further examples of components to be coated according to the invention are the following:
Seals and components of rotating machines such as pumps, gas compressors, and turbines, in particular seals between a rotating component and a stationary housing
Components subject to adhesion wear and typical fretting and pitting
Pneumatic and hydraulic facilities, in particular the “rod and cylinder” sealing system, the seal elements, and the surfaces of rods and cylinders
Units and components of engines, in particular pistons with or without piston rings, bushings and cylinder bores, valves and camshafts, and pistons and connecting rods
Components of machines exposed to corrosive chemical processes, and metallic surfaces and/or metallic substrates thereof which are chemically attacked and corroded
Components with high biocompatibility demands, in particular prostheses, implants, screws, plates, artificial joints, stents, and biomechanical and micromechanical components
Surgical instruments which in principle must be antiallergic, for example scalpels, forceps, endoscopes, cutting instruments, clamps, etc.
Components which must have surfaces that are chemically resistant to printable inks and cleaning agents, and whose surfaces require defined anti-adhesive and liquid-repellent and/or liquid-adherent properties for defined pigment metering, for example rollers, cylinders, and wipers for printers
Components in current-conducting machines, computers, and facilities requiring a heat-dissipating but electrically insulating surface coating, for example magnetic storage media and insulation for movable power supply lines
Movable media supply lines for gas, liquids, and gas- or liquid-fluidized solid media
Replacement of no longer acceptable hard chrome layers, such as those used for hydraulic pistons and cylinders in aircraft landing gears.

Further workpieces and/or materials to be coated according to the invention include cutting, boring, and screw driving tools, machining tools, ball or roller bearings, gear wheels, pinions, drive chains, sound and drive units in magnetic recording devices, and surgical and dental instruments.

In principle, in particular pairings in machines and facilities with sliding friction wear may be advantageously coated according to the invention, since these are exposed to high pressures and/or temperatures.

### DEFINITIONS

The term “minute volume” refers to a standardized gas flow into the plasma coating chamber. The dimension “sccm” used in this regard stands for standard cubic centimeters per minute, and represents a standardized volumetric flow. In vacuum pump technology this is also referred to as “gas load.” This standard denotes a defined quantity of gas (particle number) per unit time, independent of pressure and temperature. One sccm corresponds to a gas volumetric flow of V=1 cm³=1 mL per minute under standard conditions (T=20° C. and p=1013.25 hPa).

### DRAWINGS AND EXAMPLES

The present invention is explained in greater detail with reference to the figures and examples shown and discussed below. It is noted that the figures and examples are strictly illustrative in nature, and are not to be construed as limiting the invention in any way.

### Example 1

A butcher knife which was coated according to the described method (layer composition: DLC top layer with intermediate layer on an HVOF coating of metal-bonded WC—Co 83 17 tungsten carbide) had a service life three times that of a conventional butcher knife with a combination coating.

### Example 2

An industrial cutting blade for potatoes which was coated according to the described method had a service life that was extended eight times longer than that of a conventional cutting blade with a combination coating.

### Example 3

A punching tool for the manufacture of electrical plug-in connectors for the automotive industry which was coated according to the described method had a service life that was extended two times longer than that of a conventional punching tool.

FIG. 1 shows a time diagram of the variation over time of the ramps described in Table 4. The first block shows the sputtering step (a.2), and the second block represents step b) for applying the adhesive layer, as well as the ramp-like denticulation thereof, together with the top layer applied in step c).

Before or after the sputtering step (a.2), or even instead of sputtering step (a.2), step (a.1) may be inserted for applying a supporting layer.

This step may include, for example, use of a method selected from the group comprising
High-velocity flame spraying,
Plasma spraying,
Flame spraying,
Anodizing, including hard anodizing,
Electroplating,
Powder coating, and/or
Electrophoresis.

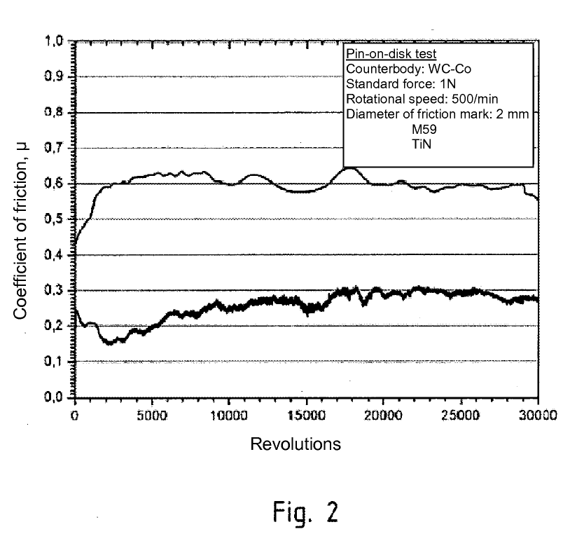

FIGS. 2-4 show the results of the physical analysis of three stainless steel workpieces, one of which is provided with a titanium nitride (TiN) coating, and the other two having coatings according to the invention (M44, layer thickness 0.81 μm, and M59, layer thickness 0.84 μm; layer composition: DLC top layer with adhesive layer on an HVOF coating of metal-bonded WC—Co 83 17 tungsten carbide). In the prior art, titanium nitride is considered to be one of the hardest and most resistant coatings for cutting, milling, and punching tools.

The friction and wear test was conducted according to SOP 4CP1 (pin-on-disk tribology) using the CSEM pin-on-disk tribometer as measuring instrument. The following process parameters were maintained:

### Stress Spectrum:

Counterbody: WC Co ball, 6 mm in diameter
Lubricant: none
Standard force FN: 1 N
Rotational speed: 500 rpm
Sliding velocity v: 52.4 mm/s
Diameter D of friction mark: 2 mm

### Boundary Conditions:

Ambient temperature: 23° C.+/−1 K
Relative humidity: 50%+/−6%

FIG. 2 shows the results of the determination of the coefficient of friction μ. It is clearly seen that the coating according to the invention, with an average coefficient of friction μ of approximately 0.3, has significant advantages over the TiN coating having an average coefficient of friction which is consistently almost twice as high.

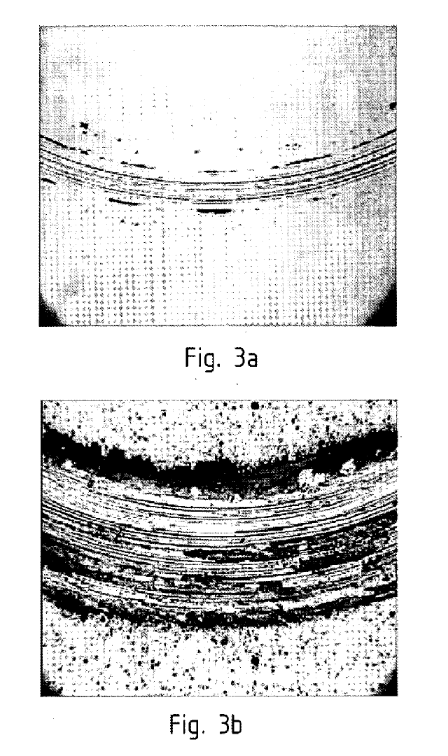

FIG. 3 shows the light optical microscopy documentation (magnification: 100×) of the wear in the friction mark after 30,000 revolutions, for the coating M59 according to the invention (FIG. 3a) and for the TiN coating (FIG. 3b). It is clearly evident that the coating according to the invention exhibits much less wear than the TiN coating.

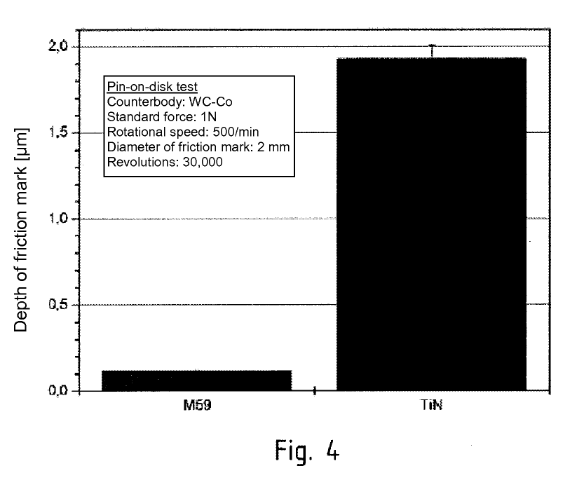

FIG. 4 shows the results of profilometric analysis of the depth of the friction mark after 30,000 revolutions. Here as well, it is clearly evident that the coating according to the invention exhibits much less wear than the TiN coating.

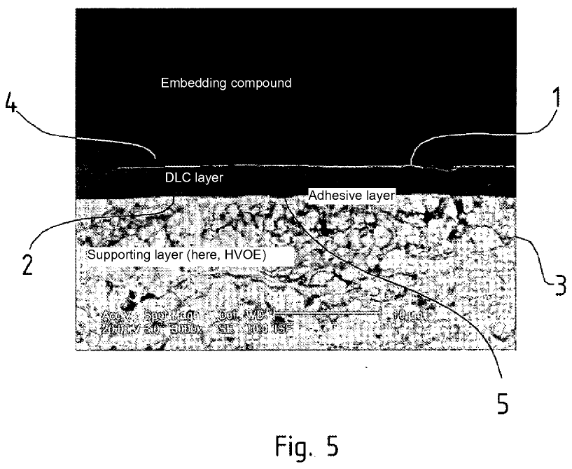

FIG. 5 shows a light optical micrograph of a section of a workpiece coated according to the invention, at 3000× magnification. The DLC layer 1, which is contrasted as a bright line against the adhesive layer 2, and the supporting layer 3 (in this case, an HVOF supporting layer) are easily identifiable. The DLC layer is approximately 4 μm thick. It is also easily seen that the embedding medium on the DLC layer has poor adhesion, causing the DLC layer to detach when the embedding medium is cut (gap 4). It is further seen that the DLC layer applied using the plasma coating method is able to compensate for unevenness (5) in the previously applied supporting layer.

1-19. (canceled)

20. A method for applying a coating to a workpiece, comprising:
a) sputtering the workpiece in the selective presence of a first plurality of different gases to form a sputtered layer and to activate the workpiece, wherein, during sputtering, the supply of the first plurality of different gases is sequentially and temporally controlled such that the stoichiometric ratio of the plurality of gases is selectively controlled over time;
b) applying an adhesive layer to the sputtered layer on the workpiece; and
c) plasma coating a high-strength top layer on the adhesive layer.

21. The method of claim 20, wherein the first plurality of different gases comprises a first gas and a second gas, and wherein the sputtering step comprises selectively decreasing the supply of the first gas in a first predetermined time sequence and selectively increasing the supply of the second gas over a second predetermined time sequence.

22. The method of claim 21, wherein the first predetermined time sequence is substantially the same as the second predetermined time sequence.

23. The method of claim 21, wherein, after the second predetermined time sequence, the first gas is washed out without residue and the only remaining gas is the second gas.

24. The method of claim 23, wherein the first gas comprises H₂.

25. The method of claim 23, wherein the first gas comprises O₂.

26. The method of claim 23, wherein the second gas comprises Ar₂.

27. The method of claim 23, wherein the first gas comprises H₂ and O₂.

28. The method of claim 27, wherein the respective supply of H₂ and O₂ are individually controlled during the first predetermined time sequence to control the relative stoichiometric ratio between the supplied H₂ and O₂.

29. The method of claim 28, wherein the first predetermined time sequence comprises a plurality of time sequences, and wherein the time sequence applied to the supply of H₂ differs from the time sequence applied to the supply of O₂.

30. The method of claim 1, further comprising applying a supporting layer to the workpiece.

31. The method of claim 30, wherein the supporting layer is applied using at least one method selected from the group consisting of: high-velocity flame spraying, plasma spraying, flame spraying, anodizing, including hard anodizing, electroplating, powder coating, and electrophoresis.

32. The method of claim 30, wherein the supporting layer comprises at least one layer selected from the group consisting of: Anodized layer, Ceramic layer, Chromium(VI) layer, and Corundum layer.

33. The method of claim 20, wherein the adhesive layer is applied to the workpiece by plasma coating.

34. The method of claim 20, wherein the adhesive layer contains elements from subgroups 6 or 7 of the periodic table.

35. The method of claim 20, wherein step b) or step c) are carried out under an inert and/or or reducing atmosphere.

36. The method of claim 21, further comprising sequentially and temporally controlling the supply of a second plurality of different gases in the transition from step b) to step c), wherein the stoichiometric ratio of the second plurality of gases is selectively controlled over time.

37. The method of claim 36, wherein the supply controlling step comprises selectively decreasing the supply of at least one gas of the second plurality of different gases in a third predetermined time sequence and selectively increasing the supply of at least one gas of the second plurality of different gases over a fourth predetermined time sequence.

37. The method of claim 36, wherein the supply of the respective different gases from the second plurality of different gases is supplied in the form of opposing ramps in the transition from step b) to step c).

38. The method of claim 20, wherein the supply of the respective different gases from the first plurality of different gases is supplied in the form of opposing ramps in the sputtering step.

39. The method of claim 20, wherein at least one of the first plurality of different gases is selected from the group containing H₂, O₂, and/or AR₂.

40. The method of claim 20, wherein the method is carried out in a plasma coating chamber having a flat high-frequency electrode for generating an electromagnetic alternating field, wherein the high-frequency electrode is electrically coupled to a frequency generator located outside the chamber, and wherein the high-frequency electrode is supplied with alternating current voltage generated by the frequency generator.

41. A use of a plasma coating chamber having a flat high-frequency electrode for generating an electromagnetic alternating field for applying a coating to a workpiece according to claim 1, wherein the high-frequency electrode is electrically coupled to a frequency generator located outside the chamber, and wherein the high-frequency electrode is supplied with alternating current voltage generated by the frequency generator.

42. A workpiece comprising a coating of at least two layers, wherein the two layers comprise an adhesive layer and a high-strength top layer, wherein the adhesive layer and top layer have a graduated transition region.

43. The workpiece of claim 42, further comprising having a supporting layer positioned between the workpiece and the adhesive layer.

44. A workpiece produced by claim 1.

45. A workpiece coated by the method of claim 1, wherein the adhesive layer and top layer have a graduated transition region.

46. The workpiece of claim 45, wherein the workpiece further comprises a supporting layer situated between the workpiece and the adhesive layer.
